(19) United States
(12) Patent Application Publication
(10) Pub. No.: US 2024/0188210 A1
(43) Pub. Date: Jun. 6, 2024

(54) PCB DESIGN TO IMPROVE HFM CONNECTOR PERFORMANCE

(71) Applicant: NIO Technology (Anhui) Co., Ltd., Hefei (CN)

(72) Inventors: Tiejun Li, San Jose, CA (US); Jianfeng Xu, Pleasanton, CA (US); Futing Lin, Santa Clara, CA (US)

(73) Assignee: NIO Technology (Anhui) Co., Ltd., Hefei (CN)

(21) Appl. No.: 18/529,693

(22) Filed: Dec. 5, 2023

Related U.S. Application Data
(60) Provisional application No. 63/430,508, filed on Dec. 6, 2022.

(51) Int. Cl. H05K 1/02

(52) U.S. Cl. CPC H05K 1/0243; H05K 2201/09609; H05K 2201/10189

(57) ABSTRACT

A printed circuit board and an apparatus including the printed circuit board are described. The printed circuit board includes a plurality of layers; a footprint fabricated on an outer layer of the plurality of layers; a plurality of signal pins and a ground pin, wherein the plurality of signal pins and the ground pin are included in the footprint. The printed circuit board includes a ground guard including: ground pads, ground layers, and a set of vias. The vias are located on the ground pads and connect the ground layers. The vias are located between the ground pin and at least one signal pin of the plurality of signal pins in a direction parallel to a plane of the plurality of layers. A quantity of the vias is based on satisfying a signal integrity threshold associated with the at least one signal pin of the plurality of signal pins.

### CROSS REFERENCE TO RELATED APPLICATION

The present application claims the benefits of and priority, under 35 U.S.C. § 119(e), to U.S. Provisional Application No. 63/430,508 filed Dec. 6, 2022, by Li et al and entitled “PCB Layout Design on a Connector Location” of which the entire disclosure is incorporated herein by reference for all purposes.

### FIELD

The present disclosure is generally directed to printed circuit board (PCB) layout design, and in particular, toward PCB layout design to improve performance of an High-speed Fachkreis Automobile or Working Group Automobile (FAKRA) Mini (HFM) connector.

### BACKGROUND

A PCB may serve as a support chassis for electronic components such as, for example, integrated circuits, resistors, capacitors, diodes, coaxial connectors, and other components. A printed circuit board assembly (PCBA) is a PCB that has been fitted with electronic components.

Improved techniques for establishing soldered connections to the PCB are desired.

### BRIEF DESCRIPTION OF THE DRAWINGS

FIG. 1 shows a perspective view of a vehicle in accordance with example aspects of the present disclosure.

FIG. 2 illustrates example PCB layout designs in accordance with aspects of the present disclosure.

FIG. 3 illustrates example via configurations in accordance with aspects of the present disclosure.

FIG. 4 illustrates a cross-sectional view associated with example via configurations in accordance with aspects of the present disclosure.

FIG. 5 illustrates an example layout configuration of vias in accordance with aspects of the present disclosure.

FIG. 6 illustrates an example layout configuration of solder mask openings in accordance with aspects of the present disclosure.

FIG. 7 illustrates a comparison image showing a bottom view of a PCBA in accordance with aspects of the present disclosure.

FIG. 8 illustrates a comparison of solder paste filling at a solder connection for a pin of a connector before and after the connector being mounted on a PCBA having a PCB layout design in accordance with aspects of the present disclosure.

FIG. 9 illustrates a comparison between simulated signal integrity results and measured results associated with some other PCBAs and simulated signal integrity results and measured results associated with a PCBA having the PCB layout design in accordance with aspects of the present disclosure.

FIG. 10 illustrates an example of a process flow that supports manufacturing a PCBA and/or a PCB in accordance with aspects of the present disclosure.

### DETAILED DESCRIPTION

Embodiments of the present disclosure will be described in connection with a PCB layout, configurations of the PCB layout, and configurations of components (e.g., vias) in the PCB layout.

A PCB may serve as a support chassis for electronic components such as, for example, integrated circuits, resistors, capacitors, diodes, coaxial connectors, and other components. A PCB provides copper and/or other metallic conductors for conveying electrical current between connected terminals of the electronic components. A PCBA is a PCB that has been fitted with electronic components (e.g., using soldering) and is ready for deployment for a target purpose.

In some PCB fabrication techniques, a solder mask (also referred to herein “solder resist”) may be applied as a coating for protecting target areas (e.g., circuit interconnections, footprints corresponding to electronic components, etc.) of the PCB during the soldering of connections to the PCB. For example, the solder mask may protect the circuitry of the PCB and provide electrical insulation. In designing a PCB, multiple vias may be placed for establishing electrical connections between electronic components located at different layers of the PCB.

Assembly of some PCBAs may be susceptible to solder issues in which the amount of solder present between a pin (also referred to herein as a terminal) of an electronic component and a corresponding contact pad of the PCB is insufficient for maintaining a reliable electrical connection. In some cases, rework to solve such instances of insufficient solder may include hand soldering or selective wave soldering techniques. However, such rework negatively impacts cycle time during mass production.

Some PCBA techniques may employ surface-mount technology (SMT) techniques and paste-in-hole (PIH) processing techniques. SMT techniques include mounting electrical components directly onto the surface of a PCB. PIH techniques include screening solder paste into and around plated through-holes (PTHs) on a PCB and placing the leads of through-hole components (e.g., connectors) in the through-holes. In some cases, running the PCB through a reflow soldering process supports terminating through-holes and SMT components in one reflow process.

Some automotive systems employ various cable solutions and connector devices associated with delivering data from a PCBA to electrical components of a vehicle. For example, some automotive systems may employ high-speed FAKRA mini (HFM) coaxial cable solutions capable of delivering 20 GHz of data speed (data rate) for a connected vehicle, which may support various applications (e.g., radar, camera, lidar, sensor applications, etc.) associated with the vehicle.

Some connector devices (e.g., HFM connectors) may have increased susceptibility to the insufficient solder issues described herein, for example, on the production floor during PCBA assembly. For example, for some connector designs (e.g., HFM connector designs), mounting a connector body to a PCB using PIH processing techniques may result in solder paste flowing into the component body instead a target hole at the PCB. The target hole may be included in a footprint area on the PCB that corresponds to the shape of the connector body. Some approaches of modifying the manufacturing process have failed to succeed at addressing such a solder issue.

In some cases, due to the mechanical structure of some connector devices (e.g., HFM connectors), hole filling (e.g., by solder paste in a PIH process) at some of the pins of the connector devices is unable to meet IPC 6012 standards. For example, for some PCB structures and PCBA manufacturing processes, implementing hole filling (e.g., using a PIH process) for mounting an HFM connector to a PCB structure may result in a solder connection that does not meet IPC 6012 standards. In an example, the solder connection at the middle GND pin of an HFM connector may fail to meet such IPC 6012 standards.

Aspects of the present disclosure support manufacturing techniques that may address insufficient solder issues described herein with respect to connector devices (e.g., HFM connectors, other coaxial connectors, etc.). According to example aspects of the present disclosure, a solder mask design and via configurations are provided that address the insufficient solder issues while maintaining or improving signal integrity associated with a connector device (e.g., an HFM connector, a coaxial connector, etc.) at a PCBA. For example, aspects of the present disclosure support maintaining signal integrity performance of a gigabit multimedia serial link (GMSL) within a communication system (e.g., a vehicle communication system). GMSL, for example, supports compression free, digital transmission of data signals across the communication system. Aspects of the present disclosure support implementations in which a connector device such as an HFM connector, a coaxial connector, a similar connector, or the like is used in other scenarios (e.g., use of the connector device as an antenna).

Example aspects of the solder mask design and via configurations are described herein with respect to the following figures.

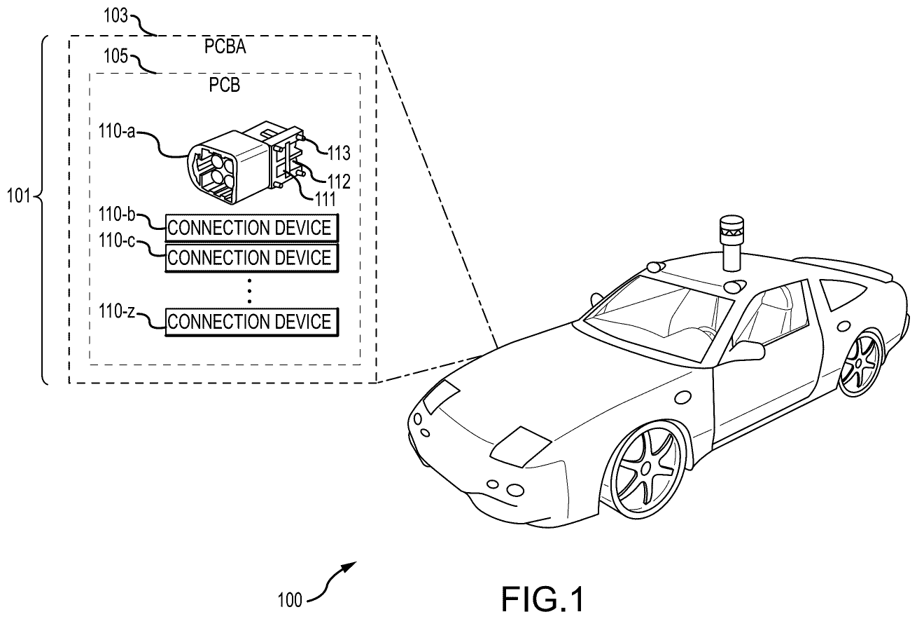

FIG. 1 shows a perspective view of a vehicle 100 in accordance with example aspects of the present disclosure. The vehicle 100 may include one or more interior components (e.g., components inside an interior space, or user space, of a vehicle 100, etc.), exterior components (e.g., components outside of the interior space, or user space, of a vehicle 100, etc.), drive systems, controls systems, structural components, etc.

Although shown in the form of a car, it should be appreciated that the vehicle 100 described herein may include any conveyance or model of a conveyance, where the conveyance was designed for the purpose of moving one or more tangible objects, such as people, animals, cargo, and the like. The term “vehicle” does not require that a conveyance moves or is capable of movement. Typical vehicles may include but are in no way limited to cars, trucks, motorcycles, busses, automobiles, trains, railed conveyances, boats, ships, marine conveyances, submarine conveyances, airplanes, space craft, flying machines, human-powered conveyances, and the like.

In some embodiments, the vehicle 100 may include a number of sensors, devices, and/or systems that are capable of assisting in driving operations, e.g., autonomous or semi-autonomous control. Examples of the various sensors and systems may include, but are in no way limited to, one or more of cameras (e.g., independent, stereo, combined image, etc.), infrared (IR) sensors, radio frequency (RF) sensors, ultrasonic sensors (e.g., transducers, transceivers, etc.), RADAR sensors (e.g., object-detection sensors and/or systems), LIDAR (Light Imaging, Detection, And Ranging) systems, odometry sensors and/or devices (e.g., encoders, etc.), orientation sensors (e.g., accelerometers, gyroscopes, magnetometer, etc.), navigation sensors and systems (e.g., GPS, etc.), and other ranging, imaging, and/or object-detecting sensors. The sensors may be disposed in an interior space of the vehicle 100 and/or on an outside of the vehicle 100. In some embodiments, the sensors and systems may be disposed in one or more portions of a vehicle 100 (e.g., a frame of the vehicle 100, a body panel, a compartment, etc.

According to example aspects of the present disclosure, the vehicle 100 may include a vehicle system 101 supportive of data communications between the sensors, devices, and/or systems of the vehicle 100. In an example, the vehicle 100 may include a PCBA 103. The PCBA 103 may include a PCB 105 to which connection devices 110 (e.g., connection device 110-a through connection device 110-z) may be mounted. In an example, the connection devices 110 may include coaxial connectors. In an example, connection device 110-a may be an HFM connector including signal pins 111, signal pin 112, and pins 113. In some examples, signal pins 111 may be data-carrying pins and signal pin 112 may be a GND pin. In some examples, pins 113 may be mounting pins or GND pins. Although example implementations are described herein with reference to connection device 110-a (e.g., an HFM connector), it is to be understood that the implementations may be applied to connection devices of different types and to mounting and/or connecting the connection devices to a PCB 105.

Example aspects of a solder mask and via configurations associated with the PCBA 103, the PCB 105, and one or more connection devices 110 are later described herein.

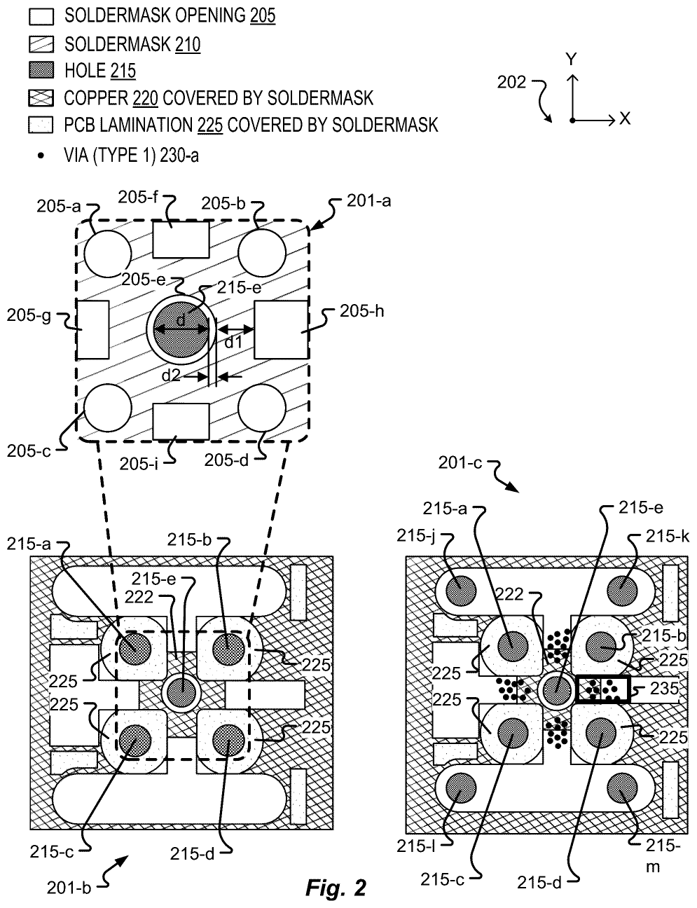

In the figures that follow, example features of the PCBA 103, PCB 105, layers thereof, the solder mask, and vias for interconnecting the layers are described in conjunction with a coordinate system 202. For example, in FIGS. 2 through 7 that follow, example features and components (e.g., with respect to dimensions, positions, spacing, directionality, etc.) are defined with respect to an X-axis, a Y-axis, and a Z-axis of the coordinate system 202.

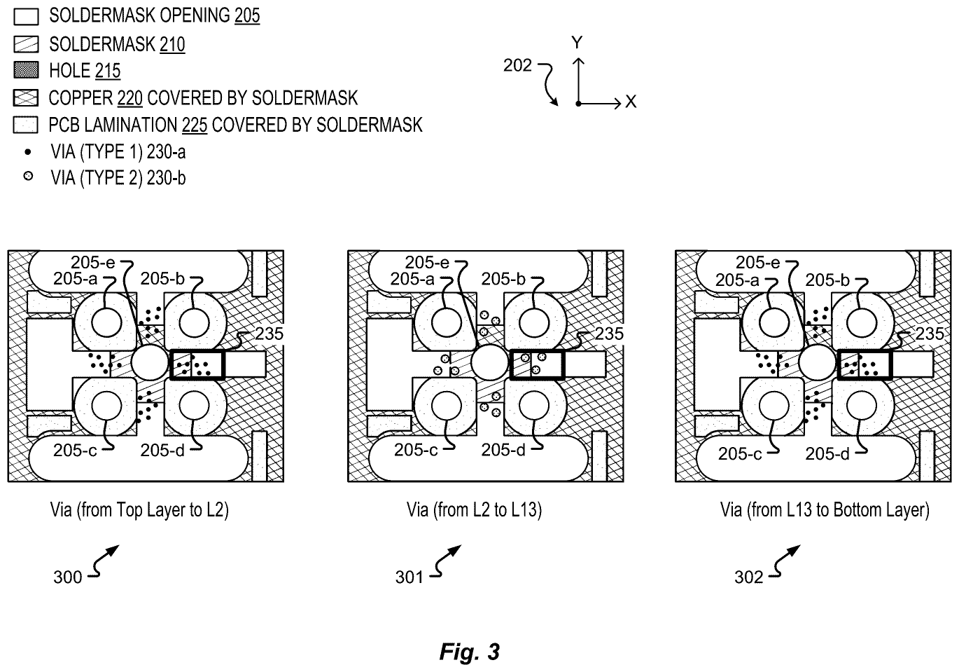

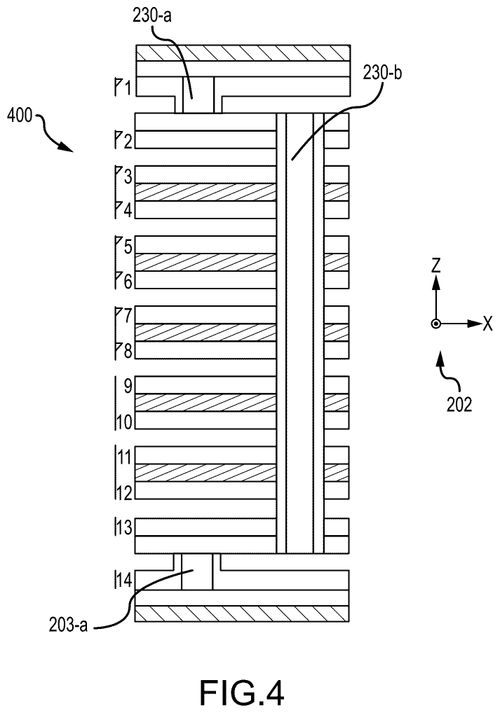

FIG. 2 illustrates example PCB designs in accordance with aspects of the present disclosure. In various implementations, the PCB design described herein may include a modified solder mask as shown in 201-b and a set of vias 230 (e.g., vias 230-a of a first type) located between two neighboring solder mask openings. FIG. 201-a is a zoom-in to show the center of the modified solder mask as illustrated in 201-b. In some cases, the example implementation 201-b may be referred herein as a “footprint” corresponding to a connection device 110. The example implementation 201-c illustrates an example top level view or bottom level view of the PCB design. For example, in example implementation 201-c, vias 230-a are visible, while vias 230-b of a second type are not visible. Examples of vias 230-b are later illustrated at FIGS. 3 and 4.

The PCB design may support any quantity of holes 215. For example, referring to example implementations 201-b and 201-c, the PCB design may include holes 215-a through 215-d that correspond to locations (and dimensions) of pins 111 of the connection device 110, hole 215-e that corresponds to the location (and dimensions) of pin 112 of the connection device 110, and holes 215-j through 215-m that correspond to locations (and dimensions) of pins 113 of the connection device 110.

Accordingly, for example, aspects of the present disclosure support (1) increasing the area of the solder mask 210 around a hole 215 (e.g., hole 215-e). The added solder mask reduces some contact area between the connection device GND pad in PCB and the connection device component body, which may thus elevate the body of the connection device by providing a support to the connection device component body. In this way, the melted solder paste will have more chance to flow into the hole 215-e instead of going to the component body itself. Aspects of the present disclosure support (2) adding more vias (e.g., vias 230) to improve the signal integrity performance and making sure the solder mask modification will not reduce the SI performance.

View 201-a is a zoom-in of the center of 201-b. Referring to view 201-a, solder mask opening 205-a through solder mask opening 205-d each may have a hole shape or a donut shape and they may correspond to locations of pins 111 of the connection device 110, and a solder mask opening 205-e may correspond to a location of pin 112 of the connection device 110. For example, solder mask opening 205-e may correspond to the hole 215-e manufactured in the PCB 105. In some aspects, the diameter of the solder mask opening 205-e may be greater than a diameter “d” of the hole 215-e. In an example, a clearance distance “d2” between an outer diameter (e.g., edge) of the solder mask opening 205-e and a ground via is equal to about 0.2 mm.

The solder mask design as shown in the zoom-in view 201-a may include solder mask opening 205-f through solder mask opening 205-i. The solder mask opening 205-f through solder mask opening 205-i may be formed and positioned so as not to overlap a dedicated GND via pattern 222 (illustrated at example implementation 201-b and example implementation 201-c). For example, GND via pattern 222 may be dedicated to pin 112 of FIG. 1.

In an example, a distance d1 between an edge associated with solder mask opening 205-e (also referred to herein, for example, as a first opening of the solder mask 210) and an edge associated with solder mask opening 205-h (also referred to herein, for example, as a second opening of the solder mask 210) may be set based on coordinates of the pin 112 and/or one or more dimensions (e.g., in the X and/or Y directions) of the pin 112. In an example, the distance d1 may be equal to about 1 mm. In some aspects, the solder mask opening 205-h is a nearest solder mask opening on a ground strip pad of the set of ground strip pads. In some aspects, the solder mask opening 205-h is located on the ground strip pad of the set of ground pads.

The solder mask design illustrated in example view 201-a supports an increased amount of solder paste to flow into the hole 215-e (e.g., compared to other PCBAs) for example, when mounting connection device 110-a to the PCB 105 using PIH techniques. In some aspects, a footprint corresponding to the zoom-in view 201-a may correspond to dimensions (e.g., X-axis and Y-axis dimensions) of the connection device 110-a. In some aspects, the footprint may be formed on an outer layer of the PCB 105.

Accordingly, for example, the zoom-in view 201-a of solder mask 210 corresponds to a component structure associated with the connection device 110-a. That is, for example, based on the component structure, the zoom-in view 201-a increases the amount of solder paste to flow into the hole 215-e in association with mounting/soldering the connection device 110-a to the PCB 105, such that in production of the PCBA 103, the hole filling is improved to meet IPC 6012 standards.

In some aspects, the solder mask configuration illustrated in zoom-in view 201-a and example implementation 201-b may result in a reduced connector area between the connection device 110-a and the PCB 105, which in some cases, may impact signal integrity performance associated with the connection device 110-a.

Aspects of the present disclosure support providing vias 230 in regions 235 located between a GND pin (e.g., pin 112 of connection device 110-a, corresponding to hole 205-e) and signal pins (e.g., pins 111 of connection device 110-a, corresponding to hole 205-a through hole 205-d) of the connection device 110-a to improve signal integrity performance. In some aspects, signal integrity improvement provided by the addition of the vias 230 may counter any decrease in signal integrity performance caused by the distortion in the signal associated with the reduced connector area between the connection device 110-a and the PCB 105.

Aspects of the present disclosure support vias 230 of different quantities, types, sizes, and/or pattern configurations. In some cases, example configurations of the vias 230 described herein may connect any combination of layers of the PCB 105. Aspects of the present disclosure support implementing different quantities, types, sizes, pattern configurations, and layer connections of the vias 230 in association with improving and/or maintaining signal integrity performance. Examples of the vias 230 are later described herein.

FIG. 3 illustrates example configurations 300 through 302 of vias 230 (and detailed structures thereof) as supported by aspects of the present disclosure. Referring to example configuration 300, the PCB 105 may include vias 230-a of a first type and/or a first size. In some aspects, the vias 230-a may extend from an outer layer (e.g., a top layer, L1) of the PCB 105 to an intermediate layer (e.g., any of L2 to L13) of the PCB 105. In an example implementation, the vias 230-a may extend from the outer layer (e.g., top layer, L1) of the PCB 105 to a first intermediate layer (e.g., L2) of the PCB 105. The example configurations 300 through 302 may include holes 215 as described with reference to FIG. 2. However, such holes 215 are omitted from FIG. 3 for clarity, so as not to obscure other aspects of FIG. 3.

Accordingly, for example, the vias 230-a may be blind vias, as the vias 230-a connect the top (or bottom) layer of the PCB 105 to one or more of inner layers of the PCB 105, without going through the entire PCB 105. A blind via, for example, is only visible from one of the outer layers of the PCB 105. In some aspects, the vias 230-a may be microvias as defined according to Institute for Printed Circuits (IPC) standards (e.g., a hole with depth to diameter aspect ratio of 1:1 or less, having a hole depth not to exceed 0.25 mm).

Referring to example configuration 301, the PCB 105 may include vias 230-b of a second type and/or a second size. Example aspects of the vias 230-b are later described with reference to FIG. 4.

Referring to example configuration 302, the PCB 105 may include vias 230-a of the first type and/or the first size (e.g., blind vias, microvias).

In some example implementations, any of the vias 230-a and vias 230-b may be non signal-carrying vias (e.g., dummy vias).

As described herein, example aspects of the present disclosure include setting quantities, types, sizes, and/or pattern configurations associated with providing vias 230 in a region 235 (or regions 235) based on a signal integrity threshold associated with a connection device 110 (e.g., connection device 110-a of FIG. 1). For example, the example aspects described herein support setting any quantities, via types, via sizes, and/or via pattern configurations of vias 230 (e.g., vias 230-a, vias 230-b) based on a signal frequency associated with the connection device 110-a and/or a signal frequency associated with a signal pin 111 (or signal pins 111) of the connection device 110-a.

In an example, aspects of the present disclosure support setting a distance between two or more vias 230 (e.g., between a via 230-a and another via 230-a, between a via 230-b and another via 230-b, between a via 230-a and a via 230-b) in a region 235 based on the signal frequency associated with the connection device 110-a and/or a signal frequency associated with a signal pin 111 (or signal pins 111) of the connection device 110-a. In some examples, aspects of the present disclosure support setting a distance between a via(s) (e.g., a via 230-a, a via 230-b, etc.) and a solder mask opening 205 (e.g., solder mask opening 205-b) corresponding to a signal pin 111 based on the signal frequency associated with the signal pin 111.

Additionally, or alternatively, aspects of the present disclosure support configuring the placement of a via 230 (e.g., a via 230-a, a via 230-b) and/or a distance between the via 230 and another component (e.g., another via 230, a solder mask opening 205, etc.) based on signal integrity described herein. In some examples, aspects of the present disclosure support configuring the placement and/or distance based on design rule constraints associated with manufacturing the PCB 105.

The configurations 300 through 302 are examples, and it is to be understood that the aspects of the present disclosure described herein support any combination of via quantities, via types, via sizes, via pattern configurations, and/or layer connections by a via, as applied to one or more areas of a PCB 105 (e.g., region 235) for achieving a signal integrity described herein.

FIG. 4 illustrates a cross-sectional view 400 corresponding to region 235 of FIG. 3. The vias 230-a may extend from an intermediate layer (e.g., any of L2 through L13) of the PCB 105 to an outer layer (e.g., a bottom layer, L14) of the PCB 105.

In the example implementation illustrated in FIG. 4, the multiple vias 230a in the Z direction may include a via 230a that extends from an outer layer (e.g., top layer, L1) of the PCB 105 to an intermediate layer (e.g., L2) of the PCB 105 and/or a via 230a that extends from the other intermediate layer (e.g., L13) of the PCB 105 to another outer layer (e.g., bottom layer, L14) of the PCB 105.

In some aspects (as illustrated in the example implementations of FIG. 4), the vias 230-b may extend from the first intermediate layer (e.g., L2) of the PCB 105 to another intermediate layer (e.g., any of L3 through L13) of the PCB 105. For example, the vias 230-b may extend from the first intermediate layer (e.g., L2) of the PCB 105 to a last intermediate layer (e.g., L13) of the PCB 105. Accordingly, for example, the vias 230b may be buried vias, in that the vias 230b connect two or more inner layers of the PCB 105, do not go through the entire PCB 105, and are not visible from any of the outer layers of the PCB 105.

With reference to FIGS. 2 through 4, aspects of the present disclosure support implementations in which one or more ground vias (e.g., a via 230-a extending from L1 to L2, a via 230-b extending from L2 to L13, and/or a via 230-a extending from L13 to L14) are added in a region located between signal pins respectively corresponding to two signals. For example, the one or more ground vias may be added in the region 235 located between a signal pin corresponding to solder mask opening 205-b and a signal pin corresponding to solder mask opening 205-d. In some example implementations, the signal pins may be associated with carrying high speed signals.

In an example, by adding the ground vias between the signal pins (and, thereby, between corresponding high speed signals), the ground vias can serve as one or more “walls” or “boundaries” to separate the high speed signals. For example, the one or more “walls” or “boundaries” may provide signal isolation between the two high speed signals, thereby reducing the crosstalk between the two high speed signals. Such implementations of the ground vias described herein may provide improved signal integrity of the two high speed signals to counter the performance issue that may be caused by the reduced contact area between the body of the connector and the connector GND pad in the PCB.

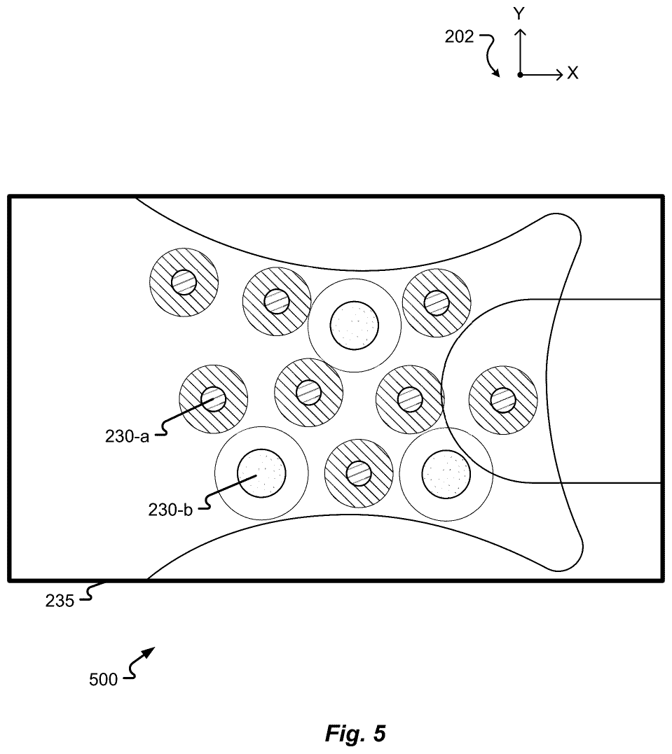

FIG. 5 is an example 500 illustrating a layout configuration of vias 230-a and vias 230-b in a region 235 as supported by aspects of the present disclosure. Example 500 is an example x-ray view of vias 230-a and vias 230-b, disposed at different layers of a PCB 105.

According to the example 500, included in the region 235 are sixteen vias 230-a (e.g., blind vias) and three vias 230-b (e.g., buried vias). However, the configuration of the vias 230-a and vias 230-b is not limited thereto.

For example, each instance of a via 230-a as viewed from the top of the XY plane may include multiple vias 230-a in the Z direction.

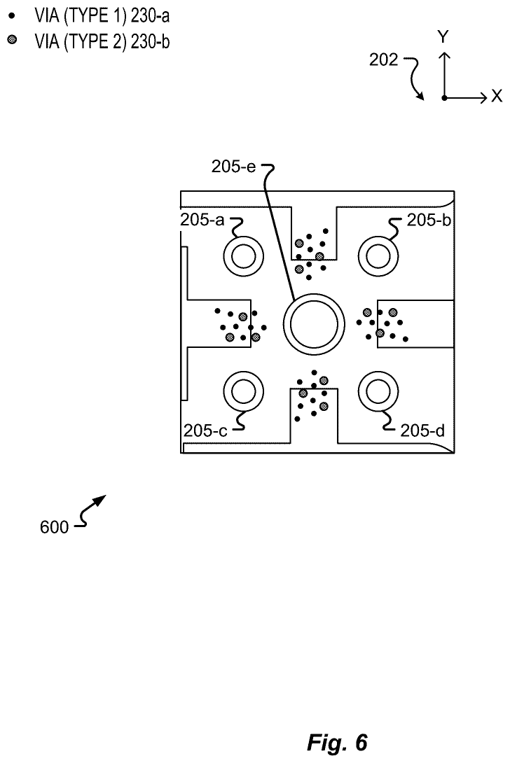

FIG. 6 is an example 600 illustrating a layout configuration of solder mask openings 205, vias 230-a, and vias 230-b as supported by aspects of the present disclosure. Example 600 is an example x-ray view of vias 230-a and vias 230-b, disposed at different layers of a PCB 105.

It is to be understood that the example shapes and sizes of vias 230-a (e.g., Type 1) and vias 230-b (e.g., Type 2) as presented in the figures herein are for illustrative purposes for distinguishing between vias 230-a and vias 230-b. The shapes and sizes of vias 230-a (e.g., Type 1) and vias 230-b (e.g., Type 2) are not limited to the example dimensions, shapes, and patterns as presented in the figures.

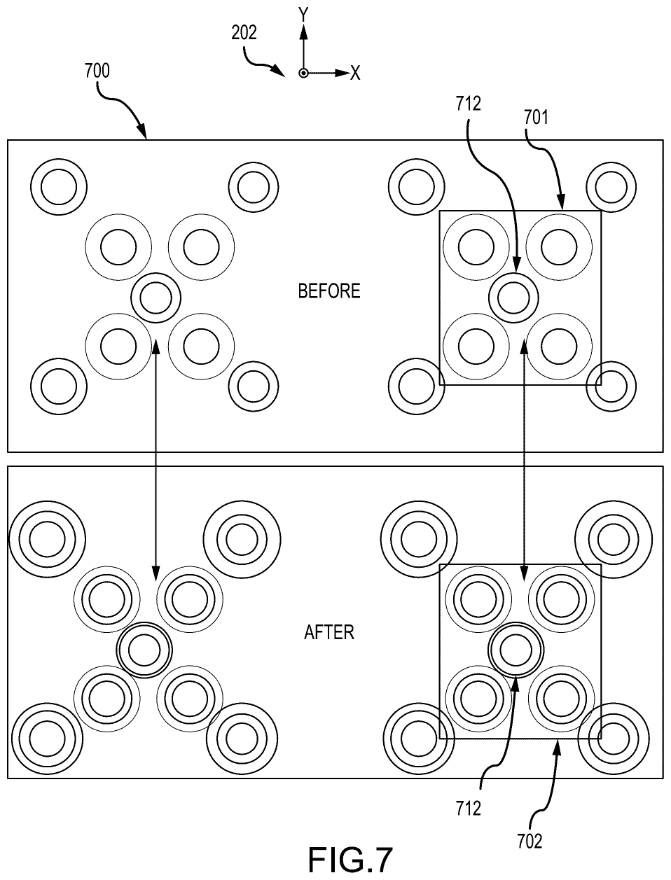

FIG. 7 illustrates a comparison image 700 showing a bottom view of the PCBA and solder connection at a pin 712 corresponding to a connector that may be mounted to other PCBAs (e.g., a regular PCBA, a PCBA according to a vendor recommended footprint) and a PCBA with the PCB layout design according to the example aspects described herein. In the “before” section of the comparison image 700, the PCB design has a region 701 corresponding to an HFM connector (e.g., connection device 110-a of FIG. 1). It is shown that the design of other PCBAs (e.g., a regular PCBA, a PCBA according to a vendor recommended footprint) causes solder paste to attach to the body of the HFM connector, thus leaving insufficient solder paste to be applied at the pin 712 (e.g., middle GND pin) of the HFM connector. In the “after” section of the comparison image 700, the PCB layout design described herein is incorporated into the PCBA, and the PCBA includes a region 702 corresponding to the HFM connector. By modifying the solder mask layer of the PCB layout design and reducing the contact area between the connector GND pad in the PCBA and the connector body, a sufficient amount of solder paste can flow into the hole associated with the pin 712 to allow sufficient mounting of the pin 712. In this way, the solder connection associated with the amount of solder paste and the mounting of the pin 712 meets IPC 6012 standards.

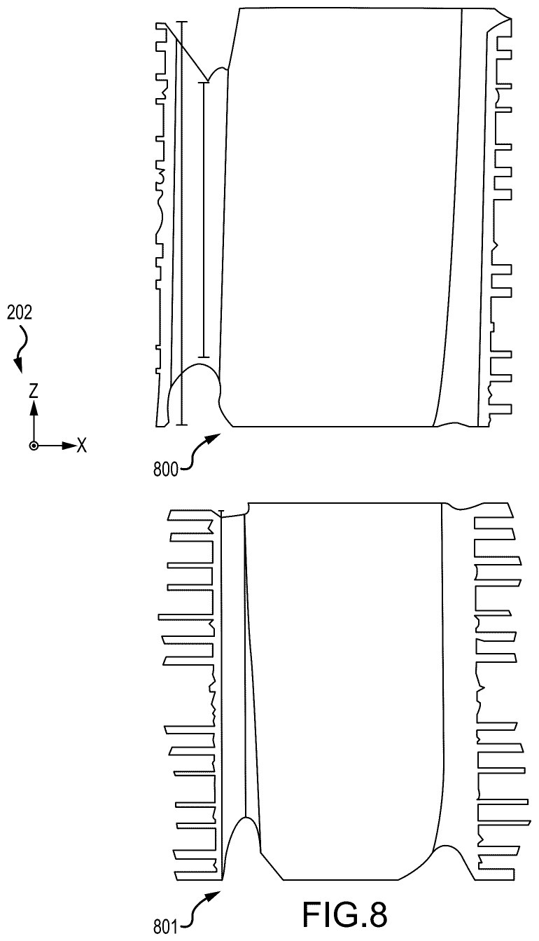

FIG. 8 illustrates a comparison of solder paste filling at a solder connection for a pin of a connector before and after the connector being mounted on a PCBA having a PCB layout design in accordance with aspects of the present disclosure. As shown, in a cross-sectional view 800 (e.g., a “before” image) of solder paste filling at a solder connection for a pin of a connector that is being mounted on some other PCBAs and a cross-sectional view 801 (e.g., an “after” image) of solder paste filling at a solder connection for a pin of a connector that is being mounted on a PCBA having the disclosed PCB layout design as described herein. As shown, implementations of the PCB layout design described herein support an increase of solder paste filling from 69% to at least 81%, thus meeting IPC 6012 standards which require a minimum solder paste filling of 75%.

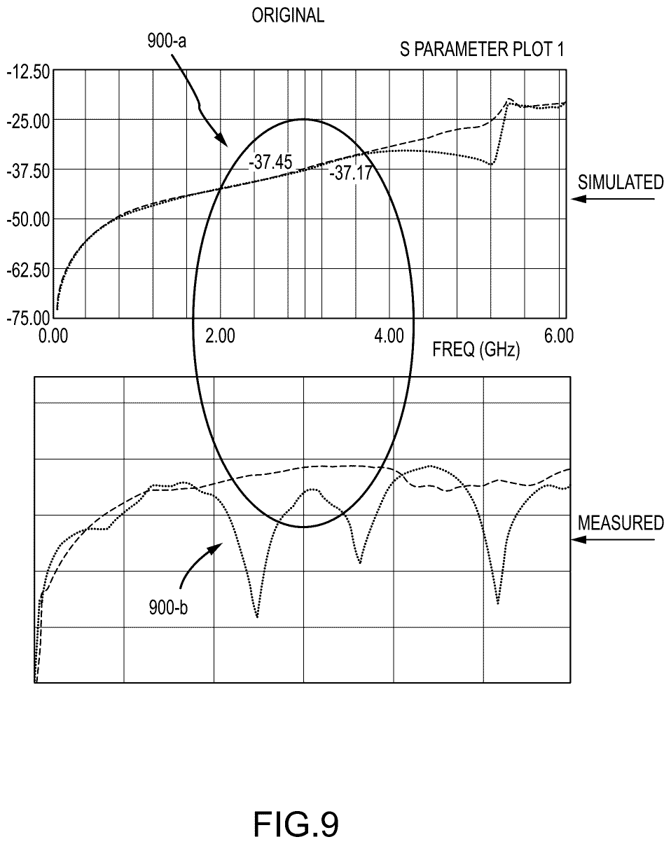

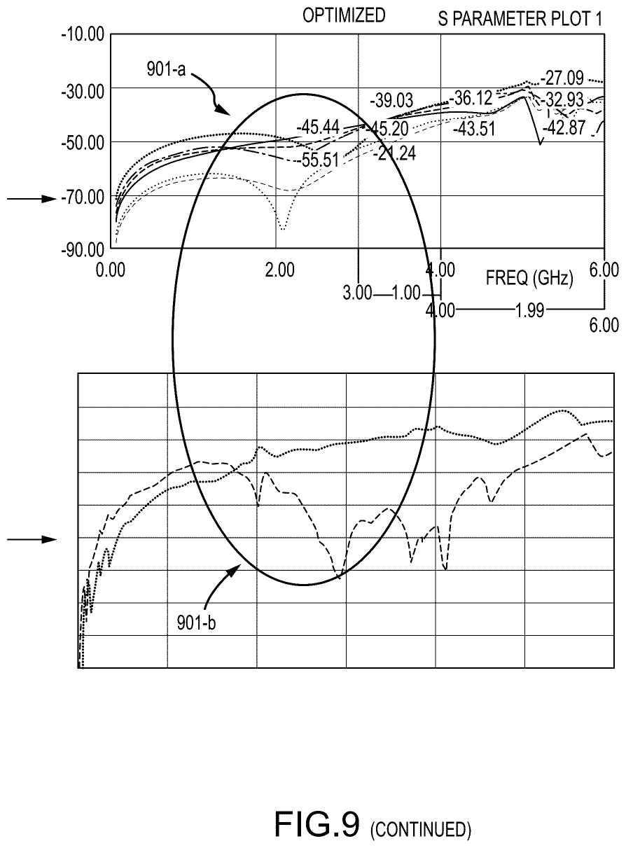

FIG. 9 illustrates a comparison between example simulated signal integrity results 900-a associated with some other PCBAs (e.g., a regular PCBA) and example simulated signal integrity results 901-a associated with a PCBA having the PCB layout design according to the example aspects described herein. FIG. 9 further illustrates example measured signal integrity results 900-b associated with some other PCBAs (e.g., the same regular PCBA) and example measured signal integrity results 901-b associated with a PCBA having the PCB layout design, according to the example aspects described herein.

The example implementations described herein with respect to a combination of a modified solder mask configuration, solder mask openings, and via configurations achieve solder connections capable of meeting target soldering goals and IPC 6012 standards (as illustrated at FIG. 7) and improvement of crosstalk between signals (as illustrated at 901-a and 901-b of FIG. 9). For example, the example implementations described herein support crosstalk reduction by about 8 db at 3 GHZ (e.g., from −37 db to −45 db at 3 GHZ), which meets GMSL requirements (e.g., <40 db@3 Ghz) for communications in a communications system.

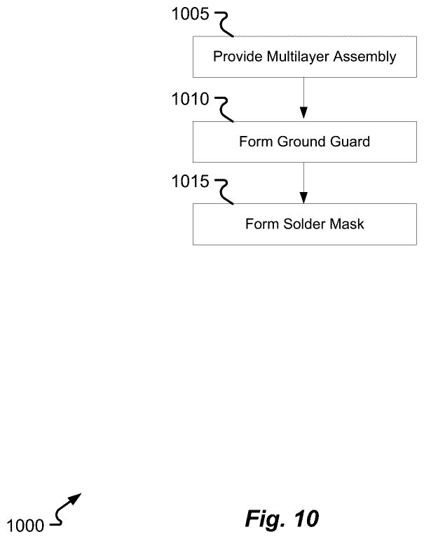

FIG. 10 illustrates an example of a process flow 1000 that supports manufacturing a PCBA and/or a PCB (e.g., PCBA 103, PCB 105) in accordance with aspects of the present disclosure.

In the following description of the process flow 1000, the operations may be performed in a different order than the order shown, or the operations may be performed in different orders or at different times. Certain operations may also be left out of the process flow 1000, or other operations may be added to the process flow 1000.

It is to be understood that a computing device supported by aspects of the present disclosure may perform the operations shown.

At 1005, the process flow 1000 may include providing a multilayer assembly including a set of outer conductive layers and a plurality of intermediate layers.

At 1010, the process flow 1000 may include forming a ground guard of the multilayer assembly, the ground guard comprising a set of ground pads, a plurality of ground layers of the plurality of layers, and a set of vias. In some aspects, the set of vias are located on the set of ground pads and connect the plurality of ground layers. In some aspects, the set of vias are located between a ground pin and at least one signal pin of a plurality of signal pins in a direction vertical to a plane of the multilayer assembly.

In some aspects, the ground pin and the plurality of signal pins are included in a footprint fabricated on an outer conductive layer of the set of outer conductive layers. In some aspects, forming the set of vias is based on satisfying a signal integrity threshold associated with the at least one signal pin.

At 1015, the process flow 1000 may include forming a solder mask on the outer conductive layer. In some aspects, a first opening of the solder mask corresponds to a boundary of a ground via included in the set of vias. In some aspects, at least a portion of a second opening of the solder mask is located between two signal pins of the plurality of signal pins. In some aspects, the solder mask overlaps at least a portion of a path corresponding to the set of ground pads.

Any of the steps, functions, and operations discussed herein can be performed continuously and automatically.

The exemplary systems and methods of this disclosure have been described in relation to vehicle system 101, a PCBA 103, a PCB 105, and a connection device 110. However, to avoid unnecessarily obscuring the present disclosure, the preceding description omits a number of known structures and devices. This omission is not to be construed as a limitation of the scope of the claimed disclosure. Specific details are set forth to provide an understanding of the present disclosure. It should, however, be appreciated that the present disclosure may be practiced in a variety of ways beyond the specific detail set forth herein.

Furthermore, while the exemplary embodiments illustrated herein show the various components of the system collocated, certain components of the system can be located remotely, at distant portions of a distributed network, such as a LAN and/or the Internet, or within a dedicated system. Thus, it should be appreciated, that the components of the system can be combined into one or more devices, such as a server, communication device, or collocated on a particular node of a distributed network, such as an analog and/or digital telecommunications network, a packet-switched network, or a circuit-switched network. It will be appreciated from the preceding description, and for reasons of computational efficiency, that the components of the system can be arranged at any location within a distributed network of components without affecting the operation of the system.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire, and fiber optics, and may take the form of acoustic or light waves, such as those generated during radio-wave and infra-red data communications.

While the flowcharts have been discussed and illustrated in relation to a particular sequence of events, it should be appreciated that changes, additions, and omissions to this sequence can occur without materially affecting the operation of the disclosed embodiments, configuration, and aspects.

A number of variations and modifications of the disclosure can be used. It would be possible to provide for some features of the disclosure without providing others.

In yet another embodiment, the systems and methods of this disclosure can be implemented in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as PLD, PLA, FPGA, PAL, special purpose computer, any comparable means, or the like. In general, any device(s) or means capable of implementing the methodology illustrated herein can be used to implement the various aspects of this disclosure. Exemplary hardware that can be used for the present disclosure includes computers, handheld devices, telephones (e.g., cellular, Internet enabled, digital, analog, hybrids, and others), and other hardware known in the art. Some of these devices include processors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or VLSI design. Whether software or hardware is used to implement the systems in accordance with this disclosure is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this disclosure can be implemented as a program embedded on a personal computer such as an applet, JAVA® or CGI script, as a resource residing on a server or computer workstation, as a routine embedded in a dedicated measurement system, system component, or the like. The system can also be implemented by physically incorporating the system and/or method into a software and/or hardware system.

Although the present disclosure describes components and functions implemented in the embodiments with reference to particular standards and protocols, the disclosure is not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

The present disclosure, in various embodiments, configurations, and aspects, includes components, methods, processes, systems and/or apparatus substantially as depicted and described herein, including various embodiments, subcombinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

Embodiments include a printed circuit board comprising: a plurality of layers; and a footprint fabricated on an outer layer of the plurality of layers; a plurality of signal pins and a ground pin, wherein the plurality of signal pins and the ground pin are included in the footprint; and a ground guard comprising: a set of ground pads; a plurality of ground layers of the plurality of layers; and a set of vias. In some aspects, the set of vias are located on the set of ground pads and configured to connect the plurality of ground layers. In some aspects, the set of vias are located between the ground pin and at least one signal pin of the plurality of signal pins in a direction parallel to a plane of the plurality of layers; and a quantity of the set of vias is based on satisfying a signal integrity threshold associated with the at least one signal pin of the plurality of signal pins.

Aspects of the above printed circuit board include a solder mask disposed on the outer layer of the plurality of layers, wherein: a first opening of the solder mask corresponds to a boundary of a ground via included in the set of vias; at least a portion of a second opening of the solder mask is located between two signal pins of the plurality of signal pins; and the solder mask overlaps at least a portion of a path corresponding to the set of ground pads. In some aspects, except for a signal via solder mask opening, the solder mask opening on the ground via/pad path is designed instead of the whole strip solder mask opening on ground pads path. Accordingly, for example, the solder mask may cover some area of the ground pads path.

Aspects of the above printed circuit board include wherein a distance between an edge associated with the first opening of the solder mask and an edge associated with the second opening of the solder mask is based on at least one of: coordinates of the ground pin; and one or more dimensions of the ground pin.

Aspects of the above printed circuit board include wherein a distance between an edge associated with the first opening of the solder mask and an edge associated with the second opening of the solder mask is equal to about 1 millimeter.

Aspects of the present disclosure include wherein: a distance between an edge of the first opening of the solder mask to an edge of the second opening of the solder mask is equal to about 1 millimeter; the second opening is a nearest solder mask opening on the GND strip pad; and the second opening is located on a ground strip pad of the set of ground pads.

Aspects of the above printed circuit board include wherein a clearance distance between an edge of the first opening of the solder mask and a ground via of the set of vias is equal to about 0.2 millimeters.

Aspects of the above printed circuit board include wherein a pattern of the set of vias is based on satisfying the signal integrity threshold. For example, aspects of the present disclosure include adding one or more ground vias (ex. a via 230-a extending from L1 to L2, a via 230-b extending from L2 to L13, and a via 230-a extending from L13 to L14 as described with reference to FIGS. 2 through 4) between two high speed signals. The ground vias can serve as one or more “walls” to separate the signals, thereby reducing the crosstalk between the two high speed signals. In this way, the signal integrity of the two high speed signals can be improved to counter the performance issue that may be caused by the reduced contact area between the body of the connector and the connector GND pad in the PCB.

Aspects of the above printed circuit board include wherein a distance between two or more vias of the set of vias is based on a signal frequency associated with the at least one signal pin of the plurality of signal pins.

Aspects of the above printed circuit board include wherein the set of vias comprise at least one of: one or more blind vias extending from the outer layer of the plurality of layers to a first intermediate layer of the plurality of layers; one or more buried vias extending from the first intermediate layer of the plurality of layers to another intermediate layer of the plurality of layers; and one or more through hole vias extending from a top layer of the plurality of layers to a bottom layer of the plurality of layers.

Aspects of the above printed circuit board include wherein the other intermediate layer is a last intermediate layer of the plurality of layers.

Aspects of the above printed circuit board include wherein the set of vias comprise at least one of: one or more microvias; and one or more through-hole vias.

Aspects of the above printed circuit board include wherein the set of vias comprise one or more non signal-carrying vias.

Aspects of the above printed circuit board include wherein the set of vias comprise: one or more first vias of a first type, a first size, or both; and one or more second vias of a second type, a second size, or both.

Aspects of the above printed circuit board include wherein each of the plurality of signal pins is located an equal distance from the ground pin.

Aspects of the above printed circuit board include wherein the plurality of signal pins comprise four signal pins.

Aspects of the above printed circuit board include wherein: the plurality of signal pins are arranged based on a square shape, a rectangular shape, a diamond shape, a circular shape, or an oval shape; and the plurality of signal pins surround the ground pin.

Aspects of the above printed circuit board include wherein the footprint is associated with a coaxial connector.

Embodiments include an apparatus comprising: a printed circuit board, wherein the printed circuit board comprises: a plurality of layers; a footprint fabricated on an outer layer of the plurality of layers; a plurality of signal pins and a ground pin, wherein the plurality of signal pins and the ground pin are included in the footprint; and a ground guard comprising: a set of ground pads; a plurality of ground layers of the plurality of layers; and a set of vias. In some aspects, the set of vias are located on the set of ground pads and connect the plurality of ground layers. In some aspects, the set of vias are located between the ground pin and at least one signal pin of the plurality of signal pins in a direction parallel to a plane of the plurality of layers. In some aspects, a quantity of the set of vias is based on satisfying a signal integrity threshold associated with the at least one signal pin of the plurality of signal pins.

Aspects of the above apparatus include a solder mask disposed on the outer layer of the plurality of layers, wherein: a first opening of the solder mask corresponds to a boundary of a ground via included in the set of vias; and at least a portion of a second opening of the solder mask is located between two signal pins of the plurality of signal pins. In some aspects, the solder mask overlaps at least a portion of a path corresponding to the set of ground pads.

Embodiments include a method comprising: providing a multilayer assembly comprising a set of outer conductive layers and a plurality of intermediate layers; and forming a ground guard of the multilayer assembly, the ground guard comprising a set of ground pads, a plurality of ground layers of the plurality of layers, and a set of vias. In some aspects, the set of vias are located on the set of ground pads and connect the plurality of ground layers. In some aspects, the set of vias are located between a ground pin and at least one signal pin of a plurality of signal pins in a direction parallel to a plane of the multilayer assembly. Aspects of the method include wherein: the ground pin and the plurality of signal pins are included in a footprint fabricated on an outer conductive layer of the set of outer conductive layers; and forming the set of vias is based on satisfying a signal integrity threshold associated with the at least one signal pin. Aspects of the method include forming a solder mask on the outer conductive layer. Aspects of the method include wherein: a first opening of the solder mask corresponds to a boundary of a ground via included in the set of vias; at least a portion of a second opening of the solder mask is located between two signal pins of the plurality of signal pins; and the solder mask overlaps at least a portion of a path corresponding to the set of ground pads.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The term “automatic” and variations thereof, as used herein, refers to any process or operation, which is typically continuous or semi-continuous, done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

Aspects of the present disclosure may take the form of an embodiment that is entirely hardware, an embodiment that is entirely software (including firmware, resident software, micro-code, etc.) or an embodiment combining software and hardware aspects that may all generally be referred to herein as a “circuit,” “module,” or “system.” Any combination of one or more computer-readable medium(s) may be utilized. The computer-readable medium may be a computer-readable signal medium or a computer-readable storage medium.

A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible medium that can contain or store a program for use by or in connection with an instruction execution system, apparatus, or device.

A computer-readable signal medium may include a propagated data signal with computer-readable program code embodied therein, for example, in baseband or as part of a carrier wave. Such a propagated signal may take any of a variety of forms, including, but not limited to, electro-magnetic, optical, or any suitable combination thereof. A computer-readable signal medium may be any computer-readable medium that is not a computer-readable storage medium and that can communicate, propagate, or transport a program for use by or in connection with an instruction execution system, apparatus, or device. Program code embodied on a computer-readable medium may be transmitted using any appropriate medium, including, but not limited to, wireless, wireline, optical fiber cable, RF, etc., or any suitable combination of the foregoing.

The terms “determine,” “calculate,” “compute,” and variations thereof, as used herein, are used interchangeably and include any type of methodology, process, mathematical operation or technique.

What is claimed is:

1. A printed circuit board comprising:
a plurality of layers;
a footprint fabricated on an outer layer of the plurality of layers;
a plurality of signal pins and a ground pin, wherein the plurality of signal pins and the ground pin are included in the footprint; and
a ground guard comprising:
a set of ground pads;
a plurality of ground layers of the plurality of layers; and
a set of vias,
wherein:
the set of vias are located on the set of ground pads and configured to connect the plurality of ground layers;
the set of vias are located between the ground pin and at least one signal pin of the plurality of signal pins in a direction parallel to a plane of the plurality of layers; and
a quantity of the set of vias is based on satisfying a signal integrity threshold associated with the at least one signal pin of the plurality of signal pins.

2. The printed circuit board of claim 1, further comprising a solder mask disposed on the outer layer of the plurality of layers, wherein:
a first opening of the solder mask corresponds to a boundary of a ground via included in the set of vias;
at least a portion of a second opening of the solder mask is located between two signal pins of the plurality of signal pins; and
the solder mask overlaps at least a portion of a path corresponding to the set of ground pads.

3. The printed circuit board of claim 2, wherein a distance between an edge associated with the first opening of the solder mask and an edge associated with the second opening of the solder mask is based on at least one of:
coordinates of the ground pin; and
one or more dimensions of the ground pin.

4. The printed circuit board of claim 2, wherein a distance between an edge associated with the first opening of the solder mask and an edge associated with the second opening of the solder mask is equal to about 1 millimeter.

5. The printed circuit board of claim 2, wherein:
a distance between an edge of the first opening of the solder mask to an edge of the second opening of the solder mask is equal to about 1 millimeter;
the second opening is a nearest solder mask opening on a ground strip pad of the set of ground pads.

6. The printed circuit board of claim 2, wherein a clearance distance between an edge of the first opening of the solder mask and a ground via of the set of vias is equal to about 0.2 millimeters.

7. The printed circuit board of claim 1, wherein a pattern of the set of vias is based on satisfying the signal integrity threshold.

8. The printed circuit board of claim 1, wherein a distance between two or more vias of the set of vias is based on a signal frequency associated with the at least one signal pin of the plurality of signal pins.

9. The printed circuit board of claim 1, wherein the set of vias comprise at least one of:
one or more blind vias extending from the outer layer of the plurality of layers to a first intermediate layer of the plurality of layers;
one or more buried vias extending from the first intermediate layer of the plurality of layers to another intermediate layer of the plurality of layers; and
one or more through hole vias extending from a top layer of the plurality of layers to a bottom layer of the plurality of layers.

10. The printed circuit board of claim 9, wherein the another intermediate layer is a last intermediate layer of the plurality of layers.

11. The printed circuit board of claim 1, wherein the set of vias comprise at least one of:
one or more microvias; and
one or more through-hole vias.

12. The printed circuit board of claim 1, wherein the set of vias comprise one or more non signal-carrying vias.

13. The printed circuit board of claim 1, wherein the set of vias comprise:
one or more first vias of a first type, a first size, or both; and
one or more second vias of a second type, a second size, or both.

14. The printed circuit board of claim 1, wherein each of the plurality of signal pins is located an equal distance from the ground pin.

15. The printed circuit board of claim 1, wherein the plurality of signal pins comprise four signal pins.

16. The printed circuit board of claim 1, wherein:
the plurality of signal pins are arranged based on a square shape, a rectangular shape, a diamond shape, a circular shape, or an oval shape; and
the plurality of signal pins surround the ground pin.

18. An apparatus comprising:
a printed circuit board, wherein the printed circuit board comprises:
a plurality of layers;
a footprint fabricated on an outer layer of the plurality of layers;
a plurality of signal pins and a ground pin, wherein the plurality of signal pins and the ground pin are included in the footprint; and
a ground guard comprising:
a set of ground pads;
a plurality of ground layers of the plurality of layers; and
a set of vias,
wherein:
the set of vias are located on the set of ground pads and connect the plurality of ground layers;
the set of vias are located between the ground pin and at least one signal pin of the plurality of signal pins in a direction parallel to a plane of the plurality of layers; and
a quantity of the set of vias is based on satisfying a signal integrity threshold associated with the at least one signal pin of the plurality of signal pins.

19. The apparatus of claim Error! Reference source not found., further comprising a solder mask disposed on the outer layer of the plurality of layers, wherein:
a first opening of the solder mask corresponds to a boundary of a ground via included in the set of vias;
at least a portion of a second opening of the solder mask is located between two signal pins of the plurality of signal pins; and
the solder mask overlaps at least a portion of a path corresponding to the set of ground pads.

17. A method comprising:
providing a multilayer assembly comprising a set of outer conductive layers and a plurality of intermediate layers;
forming a ground guard of the multilayer assembly, the ground guard comprising a set of ground pads, a plurality of ground layers of the plurality of intermediate layers, and a set of vias,
wherein:
the set of vias are located on the set of ground pads and connect the plurality of ground layers;
the set of vias are located between a ground pin and at least one signal pin of a plurality of signal pins in a direction parallel to a plane of the multilayer assembly;
the ground pin and the plurality of signal pins are included in a footprint fabricated on an outer conductive layer of the set of outer conductive layers; and
forming the set of vias is based on satisfying a signal integrity threshold associated with the at least one signal pin; and
forming a solder mask on the outer conductive layer, wherein:
a first opening of the solder mask corresponds to a boundary of a ground via included in the set of vias;
at least a portion of a second opening of the solder mask is located between two signal pins of the plurality of signal pins; and
the solder mask overlaps at least a portion of a path corresponding to the set of ground pads.
